(19) United States
(12) Patent Application Publication
(10) Pub. No.: US 2012/0257337 A1
(43) Pub. Date: Oct. 11, 2012

(54) ELECTRONIC EQUIPMENT SYSTEM AND ELECTRONIC EQUIPMENT

(75) Inventor: Tatsuaki Amemura, Osaka (JP)

(73) Assignee: Sharp Kabushiki Kaisha, Osaka (JP)

(21) Appl. No.: 13/440,490

(22) Filed: Apr. 5, 2012

(30) Foreign Application Priority Data
Apr. 5, 2011 (JP) JP2011-083863

(51) Int. Cl. H05K 7/00

(52) U.S. Cl. 361/679.01

(57) ABSTRACT

The connection device 2 has a level prescribing section 21 in which the level of a function executed at the electronic equipment 1 is determined in advance, while the electronic equipment 1 determines details of the function corresponding to the level. When the connection device 2 is connected to the electronic equipment 1, the setting processing section 31 detects the level determined at the level prescribing section 21 and sets a function actually executable by the electronic equipment 1 in accordance with the detected level. This allows plural types of electronic equipment 1 having different functions to be manufactured without the need for preparing different hardware configurations for the electronic equipment 1. Furthermore, a worker without expert knowledge can easily set the function of the electronic equipment 1 only by connecting the connection device 2 to the electronic equipment 1.

### CROSS-REFERENCE TO RELATED APPLICATIONS

This Nonprovisional application claims priority under 35 U.S.C.§119(a) on Patent Application No.2011-083863 filed in Japan on Apr. 5, 2011, the entire contents of which are hereby incorporated by reference.

### BACKGROUND

1. Technical Field

The present invention relates to an electronic equipment system including an electronic equipment and a connection device connected to the electronic equipment, and also relates to the electronic equipment.

2. Description of Related Art

An electronic equipment such as a notebook PC (Personal Computer), a game machine or a television set is often provided with a connection interface to be connected to an external device for performing data transfer. An example of the connection interface includes a USB (Universal Serial Bus). Japanese Utility Model Registration No. 3151486 discloses USB 3.0 as an example of the connection interface.

When an electronic equipment is manufactured, it is common to manufacture plural types of electronic equipment having different functions, such as a low-end product, a high-end product, a product for domestic use and a product for international use. Conventionally, plural types of electronic equipment having different functions have been realized by preparing different hardware configurations, e.g., by preparing different types or different numbers of mounted parts.

### SUMMARY OF THE INVENTION

Such a method of realizing plural types of electronic equipment by preparing different types of hardware configurations may cause an error in mounting different parts. If quality control is performed to prevent such an error in mounting parts from occurring, a cost for such control will be necessary. Moreover, a dedicated facility and a worker with expert knowledge will be required to manufacture plural types of electronic equipment having different hardware configurations. Such a method of realizing plural types of electronic equipment by making different hardware configurations, therefore, has problems in terms of cost, facilities and manpower.

The present invention has been contrived in view of the above circumstances. An object of the invention is to provide an electronic equipment system having an electronic equipment with different functions without having different hardware configurations to easily realize plural types of electronic equipment, and to also provide the electronic equipment.

In an electronic equipment system according to the present invention including an electronic equipment and a connection device detachable from the electronic equipment, the connection device includes a level prescribing section at which a level of a function to be executed by the electronic equipment is determined. The electronic equipment includes: a detection section for detecting the level determined at the level prescribing section when the connection device is connected to the electronic equipment; and a setting section for setting details of the function to be executed by the electronic equipment in accordance with the level detected by the detection section.

In the electronic equipment system according to the present invention, the setting section includes: a functional information storage section storing a plurality of types of functional information for determining details of the function executable by the electronic equipment; and a level association section associating a level of a function to each of the plurality of types of functional information; and a selection section for selecting any one of the plurality of types of functional information in accordance with the level detected by the detection section. The electronic equipment further includes a processing section for performing a process of executing a function determined in the functional information selected by the selection section after the connection device is detached from the electronic equipment.

In the electronic equipment system according to the present invention, the electronic equipment further includes a plurality of function executing sections each having an individual function. The setting section includes: a level range storage section storing a range of levels which allows operation of each of the plurality of function executing sections; and an operation setting section which enables operation of a function executing section when the level detected by the detection section is included in a range of levels allowing operation of the function executing section, and disables operation of a function executing section when the level detected by the detection section is not included in the range of levels allowing operation of the function executing section, among the plurality of function executing sections.

In the electronic equipment system according to the present invention, the electronic equipment is connected to the connection device by an interface for transmitting data through a plurality of signal lines, and the detection section is connected to the level prescribing section through a part of the plurality of signal lines when the electronic equipment is connected to the connection device, and detects a level determined at the level prescribing section through the part of the signal lines.

An electronic equipment according to the present invention that is detachable from a connection device and that can execute a plurality of types of functions includes: a detection section for detecting a level determined at a connection device, in which a level of a function to be executed is predetermined, when the connection device is connected to the electronic equipment; and a setting section for setting details of a function to actually be executed among the plurality of types of functions so as to be able to execute a function in accordance with the level detected by the detection section.

According to an aspect of the present invention, the level of the function executed at the electronic equipment is predetermined at the connection device. The electronic equipment detects the level determined at the connected connection device and sets the details of the function, which is actually executed, in accordance with the detected level. Without preparing different hardware configurations in the electronic equipment, appropriate setting can be performed only by connecting appropriate connection device to the electronic equipment, and thus plural types of electronic equipment having different functions can be manufactured.

According to another aspect of the present invention, the electronic equipment stores plural types of functional information which determines details of executable functions, selects functional information corresponding to the detected level of the function, and controls the function in accordance with the selected functional information. Electronic equipment that executes any one of the plural types of functions can be implemented only by connecting the electronic equipment to the connection device in which an appropriate level of the function is determined.

According to another aspect of the invention, the electronic equipment including plural function executing sections enables or disables the operation of each of the plural function executing sections in accordance with the level of a function determined at the connection device. The electronic equipment executes the processing by the functional executing section for which the operation is enabled, to realize any one of the plural types of electronic equipment.

According to a further aspect of the invention, the electronic equipment detects the level of a function through a signal line used for the interface performing data transmission when the connection device is connected thereto. No special interface is required for setting electronic equipment.

According to the present invention, plural types of electronic equipment can be manufactured at low cost compared to the method of realizing plural types of electronic equipment by preparing different hardware configurations. Furthermore, it is not necessary to provide facilities for making different hardware configurations for electronic equipment, allowing a worker without expert knowledge to easily perform appropriate setting for electronic equipment.

The above and further objects and features of the invention will more fully be apparent from the following detailed description with accompanying drawings.

### BRIEF DESCRIPTION OF THE SEVERAL VIEWS OF THE DRAWINGS

FIG. 1 is a conceptual view illustrating the appearance of an electronic equipment system of the present invention;

FIG. 2 is a block diagram illustrating the internal functional configuration of electronic equipment and a connection device included in the electronic equipment system according to Embodiment 1;

FIG. 3 is a circuit diagram illustrating the first example of the internal configuration of a level prescribing section;

FIG. 4 is a circuit diagram illustrating the second example of the internal configuration of the level prescribing section;

FIG. 5 is a conceptual view illustrating an example of a form in which a functional information storage section stores functional information in Embodiment 1;

FIG. 6 is a conceptual view illustrating an example of details of information in which a functional level and a designation number are associated with each other in Embodiment 1;

FIG. 7 is a flowchart illustrating the procedure of processing performed when the connection device is connected to the electronic equipment in Embodiment 1;

FIG. 8 is a flowchart illustrating the procedure of processing performed when the electronic equipment is activated in Embodiment 1;

FIG. 9 is a block diagram illustrating the internal functional configuration of the electronic equipment according to Embodiment 2;

FIG. 10 is a conceptual view illustrating an example of details of the functional information stored in the functional information storage section in Embodiment 2;

FIG. 11 is a conceptual view illustrating an example of details of information in which a functional level and a designation number are associated with each other in Embodiment 2; and

FIG. 12 is a flowchart illustrating the procedure of processing executed when the electronic equipment is activated in Embodiment 2.

### DETAILED DESCRIPTION

The present invention will specifically be described below with reference to the drawings illustrating embodiments thereof.

### Embodiment 1

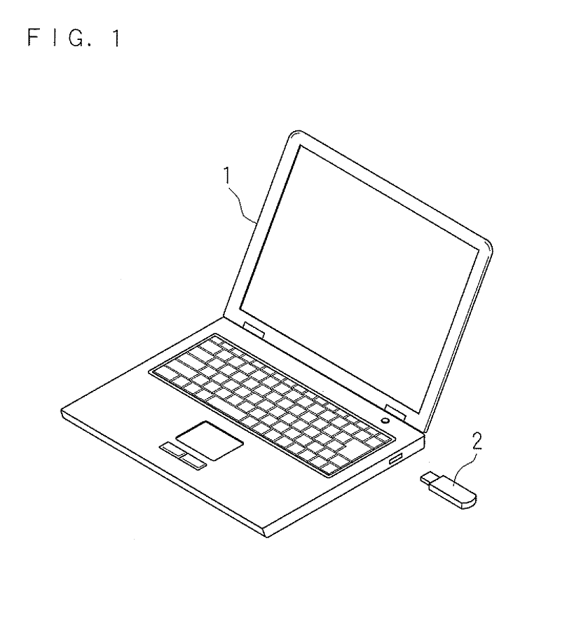

FIG. 1 is a conceptual view illustrating the appearance of an electronic equipment system of the present invention. The electronic equipment system of the present invention includes electronic equipment 1, such as a notebook PC or a game machine, and a connection device 2. The electronic equipment 1 has a configuration which can realize any one of plural types of functions depending on setting. For example, the electronic equipment 1 is provided with all the plural types of functions according to areas to which the electronic equipment 1 is to be shipped, such as Japan, the United States of America (hereinafter referred to as USA) and China. Setting is performed for any one of the areas and a function corresponding to the setting among the plural types of functions is actually executed. More specifically, the electronic equipment 1 which is set for any one of the areas executes the function of displaying a language used in the set area, but does not execute the function of displaying the other languages. The connection device 2 can be detachable to the electronic equipment 1, and makes the electronic equipment 1 perform setting when it is connected to the electronic equipment 1. At a time point before the electronic equipment 1 is for sale, the connection device 2 is connected to the electronic equipment 1 for setting performed in a factory, a dealer or the like. At the time when the electronic equipment is sold, the connection device 2 is not sold.

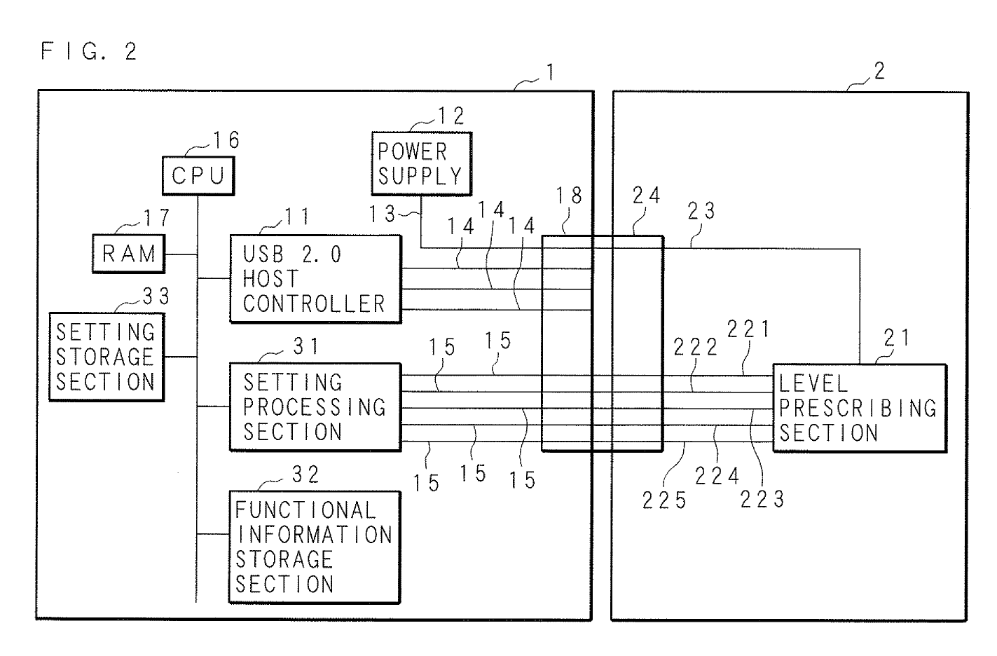

FIG. 2 is a block diagram illustrating the internal functional configuration of the electronic equipment 1 and the connection device 2 included in the electronic equipment system according to Embodiment 1. The electronic equipment 1 includes a USB 3.0 socket 18 which is a connector for connecting the connection device 2 thereto. The USB 3.0 socket 18 is a connector compliant with USB 3.0 which is an interface for inputting/outputting data. The USB 3.0 is an interface for inputting/outputting data using nine signal lines. Nine signal lines are connected to the USB 3.0 socket 18. Moreover, USB 3.0 has backward compatibility with USB 2.0. The USB 2.0 is an interface for inputting/outputting data using four signal lines. Among nine signal lines connected to the USB 3.0 socket 18, four signal lines are used for USB 2.0. The four signal lines used for USB 2.0 include a power line 13 as well as three signal lines 14, 14 and 14. Furthermore, the nine signal lines connected to the USB 3.0 socket 18 include five signal lines 15, 15, . . . that are not used for USB 2.0.

The power line 13 is connected to a power supply 12 which supplies power to the connection device 2 connected to the USB 3.0 socket 18. The signal lines 14, 14 and 14 are connected to the USB 2.0 host controller 11. The USB 2.0 host controller 11 executes processing of data input/output at the host side in accordance with a communication protocol for USB 2.0. The USB 2.0 host controller 11 is connected to a CPU (Central Processing Unit) 16 which executes information processing required for the electronic equipment 1. The CPU 16 is connected to a RAM (Random Access Memory) which stores data generated along with the information processing. The CPU 16 is additionally connected to various devices (not shown), such as a display, for executing various types of processing required for the electronic equipment 1.

Moreover, the electronic equipment 1 includes a setting processing section 31 for performing the processing for setting a function executable by the electronic equipment 1. The setting processing section 31 is connected to the CPU 16. The setting processing section 31 is configured with a microcontroller including an operation section for performing operation, a memory for storing a program necessary for operation and temporary information associated with operation, an input terminal and an output terminal. Five signal lines 15, 15, . . . are connected to the input terminal of the setting processing section 31. Note that the setting processing section 31 may be configured with a PLD (Programmable Logic Device) or a general purpose logic IC. Moreover, the setting processing section 31 may have a configuration including plural ICs.

The electronic equipment 1 further includes a functional information storage section 32 for storing plural functional information in which details of plural functions, any one of which being executable depending on the setting, are defined, and also includes a setting storage section 33 for storing information for designating any one of the plural functional information. Each of the functional information storage section 32 and the setting storage section 33 is a non-volatile memory, and is connected to the CPU 16. The setting processing section 31, the functional information storage section 32 and the setting storage section 33 correspond to the detection section and the setting section in the present invention.

The connection device 2 includes a USB 3.0 plug 24 which is a connector for connecting the USB 3.0 socket 18 thereto. The USB 3.0 plug 24 is a connector in compliant with USB 3.0. The USB 3.0 plug 24 is connected to a power line 23 and to five signal lines 221, 222, 223, 224 and 225 that are not used for USB 2.0. Moreover, the connection device 2 includes a level prescribing section 21 in which a functional level indicating the level of a function actually executed at the electronic equipment 1 is determined in advance. The level prescribing section 21 is connected to signal lines 221, 222, 223, 224 and 225. The level prescribing section 21 is also connected to the power line 23. The level prescribing section 21 operates when electric power is supplied from the electronic equipment 1 through the power line 23.

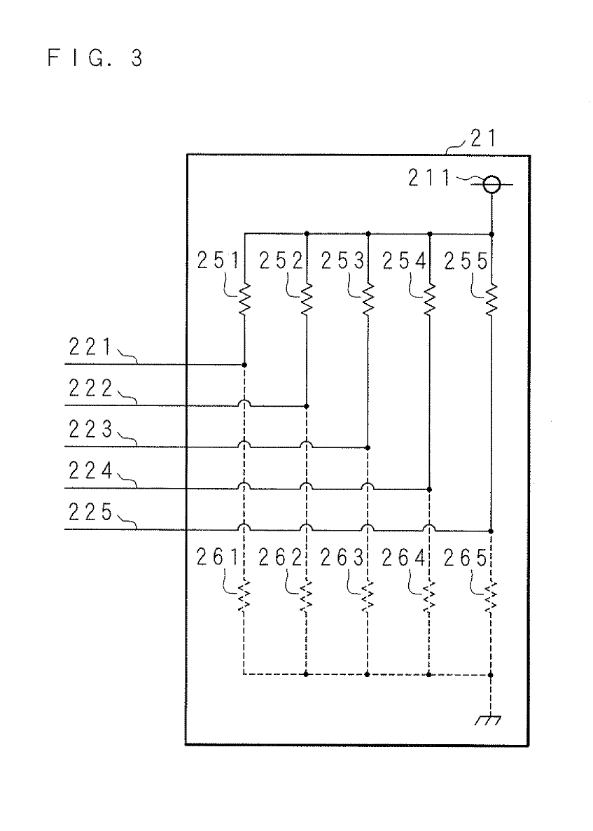

FIG. 3 is a circuit diagram illustrating the first example of the internal configuration of the level prescribing section 21. The level prescribing section 21 includes a constant potential point 211 connected to the power line 23. The constant potential point 211 is supplied with electric power from the electronic equipment 1 through the power line 23, and generates a predetermined constant potential. The level prescribing section 21 includes either a pull-up resistance 251 connected to the constant potential point 211 or a pull-down resistance 261 connected to the ground. A signal line 221 is connected to either pull-up resistance 251 or pull-down resistance 261. In the state where the signal line 221 is connected to the pull-up resistance 251, the potential of the signal line 221 becomes high. On the other hand, when the signal line 221 is connected to the pull-down resistance 261, the potential of the signal line 221 becomes low. The high potential is assumed as a signal of “1” whereas the low potential is assumed as a signal of “0.” In other words, the signal line 221 outputs “1” when it is connected to the pull-up resistance 251, whereas the signal line 221 outputs “0” when it is connected to the pull-down resistance 261.

In addition, the level prescribing section 21 includes either a pull-up resistance 252 or a pull-down resistance 262. A signal line 222 is connected to either pull-up resistance 252 or pull-down resistance 262. The level prescribing section 21 also includes either a pull-up resistance 253 or a pull-down resistance 263. A signal line 223 is connected to either pull-up resistance 253 or pull-down resistance 263. The level prescribing section 21 further includes either a pull-up resistance 254 or a pull-down resistance 264. A signal line 224 is connected to either pull-up resistance 254 or pull-down resistance 264. Moreover, the level prescribing section 21 includes either a pull-up resistance 255 or a pull-down resistance 265. A signal line 225 is connected to either pull-up resistance 255 or pull-down resistance 265.

When the pull-up resistances 251, 252, 253, 254 and 255 indicated by solid lines in FIG. 3 are mounted while the pull-down resistances 261, 262, 263, 264 and 265 indicated by broken lines are not mounted, the signal lines 221, 222, 223, 224 and 225 output {1, 1, 1, 1, 1}. If, on the other hand, the pull-up resistances 251, 252, 253, 254 and 255 are not mounted while the pull-down resistances 261, 262, 263, 264 and 265 are mounted, the signal lines 221, 222, 223, 224 and 225 output {0, 0, 0, 0, 0}. By mounting either the pull-up resistances or pull-down resistances connected to the respective signal lines, the level prescribing section 21 is set to output any one of the 2⁵ signals from {0, 0, 0, 0, 0} to {1, 1, 1, 1, 1}. The signal output by the level prescribing section 21 corresponds to a signal indicating a functional level. The level prescribing section 21 has an internal circuit determined in advance to output a signal indicating a predetermined functional level.

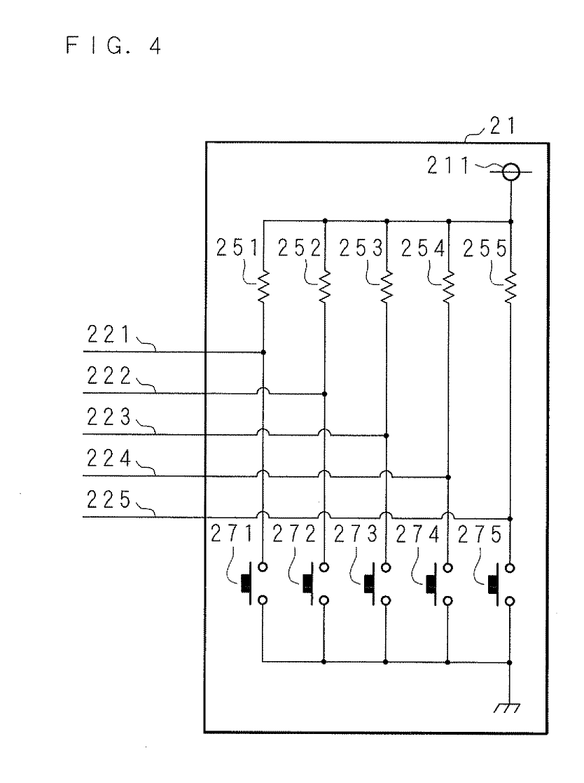

FIG. 4 is a circuit diagram illustrating the second example of the internal configuration of the level prescribing section 21. The level prescribing section 21 includes the pull-up resistance 251 and a pull-down switch 271, which are connected to the signal line 221. As shown in FIG. 4, when the pull-down switch 271 is turned off, the potential of the signal line 221 becomes high, outputting “1.” When, on the other hand, the pull-down switch 271 is turned on, the potential of the signal line 221 becomes low, outputting “0.” Similarly, the level prescribing section 21 includes pull-up resistances 252, 253, 254 and 255 as well as pull-down switches 272, 273, 274 and 275. The signal line 222 is connected to the pull-up resistance 252 and pull-down switch 272. The signal line 223 is connected to the pull-up resistance 253 and pull-down switch 273. The signal line 224 is connected to the pull-up resistance 254 and pull-down switch 274. The signal line 225 is connected to the pull-up resistance 255 and pull-down switch 275.

By switching “on” and “off” of each of the pull-down switches 271, 272, 273, 274 and 275, the level prescribing section 21 is set to output any one of the 2⁵ signals from {0, 0, 0, 0, 0} to {1, 1, 1, 1, 1}. If, for example, all of the pull-down switches 271, 272, 273, 274 and 275 are turned off as shown in FIG. 4, the signals of {1, 1, 1, 1, 1} are output. In other words, at the level prescribing section 21, the functional level is determined in accordance with whether each of the pull-down switches 271, 272, 273, 274 and 275 are “on” or “off.” The level prescribing section 21 is set in advance to output a signal indicating a predetermined functional level. Note that the level prescribing section 21 may have a configuration in which each pull-down switch is so fixed as not to change the functional level later, or a configuration in which the functional level can be changed by switching “on” and “off” of each pull-down switch using a DIP switch or the like.

Though FIGS. 3 and 4 show the examples where all of the five signal lines 221, 222, 223, 224 and 225 are used to output a signal of a functional level, the level prescribing section 21 may alternatively take a form of outputting a signal of the functional level using a part of the signal lines. The level prescribing section 21 may, for example, use only the signal line 221 to output “0” or “1.” The level prescribing section 21 may also be configured with a non-volatile memory in which digital data indicating the functional level is stored. The level prescribing section 21 with such a configuration has the functional level identified by storing predetermined digital data, and the functional level is read out through any one of the signal lines 221, 222, 223, 224 and 225. This configuration allows more variations of functional levels than 2⁵ levels to be set. The level prescribing section 21 may also have a configuration in which digital data indicating the functional level can or cannot be rewritten. Furthermore, the level prescribing section 21 may be configured to determine a functional level with a method other than the above.

The USB 3.0 plug 24 is connected to the USB 3.0 socket 18, so that the electronic equipment 1 is connected to the connection device 2. The power line 23 is connected to the power line 13, while the signal lines 221, 222, 223, 224 and 225 are connected to the signal lines 15, 15, . . . , respectively. The level prescribing section 21 is connected to the setting processing section 31 through the signal lines 221, 222, 223, 224 and 225 as well as the signal lines 15, 15, . . . . In addition, electric power is supplied from the power supply 12 to the level prescribing section 21 through the power lines 13 and 23.

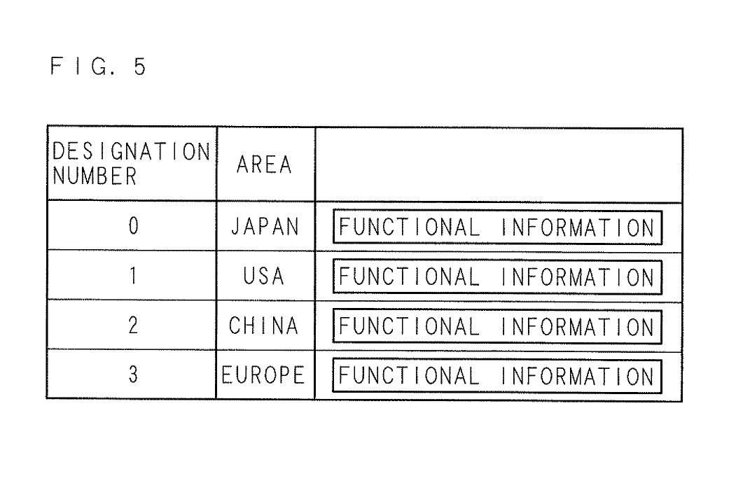

FIG. 5 is a conceptual view illustrating an example of a form in which a functional information storage section 32 stores functional information in Embodiment 1. Functional information, which indicates the details of the functions to be executed by the electronic equipment 1, is stored in association with each of the areas to which the electronic equipment 1 is to be shipped. In the example of FIG. 5, Japan, the USA, China and Europe are recorded as the areas, while functional information associated with each area is stored. Each piece of functional information includes information for designating a power voltage, a language used or the like. The functional information associated with each area is denoted by a designation number designating each piece of information with a number.

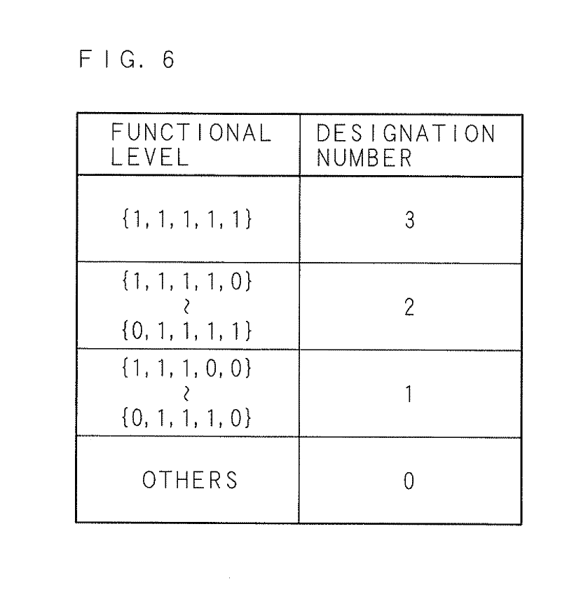

Furthermore, the functional information storage section 32 stores information in which a functional level is associated with a designation number. FIG. 6 is a conceptual view illustrating an example of details of information in which a functional level and a designation number are associated with each other in Embodiment 1. The functional information storage section 32 stores information indicating a range of the functional level corresponding to each designation number. In the example shown in FIG. 6, the signals of {1, 1, 1, 1, 1} indicating the functional level are associated with the designation number “3,” while the signals in the range between {1, 1, 1, 1, 0} and {0, 1, 1, 1, 1} indicating the functional level are associated with the designation number “2.” Moreover, the signals in the range between {1, 1, 1, 0, 0} and {0, 1, 1, 1, 0} indicating the functional level are associated with the designation number “1,” while the signals in the range other than the above indicating the functional level are associated with the designation number “0.” Furthermore, in the state where the level prescribing section 21 is configured with a non-volatile memory, the functional information storage section 32 stores, for example, specific data of the functional levels in association with the respective designation numbers.

Next, processing for setting the function of the electronic equipment 1 will be described. In a factory, a dealer or the like, a worker connects the electronic equipment 1 to the connection device 2 to set the function of the electronic equipment 1. For example, in the level prescribing section 21 in the connection device 2, the functional level is determined in accordance with the area to which the electronic equipment 1 is to be shipped, e.g. to Japan or to the USA. A label indicating the area of shipment is shown on the outer surface of the connection device 2.

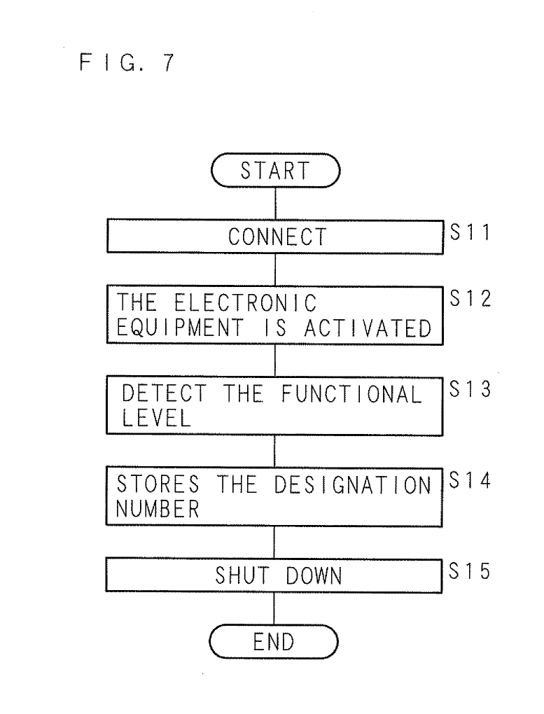

FIG. 7 is a flowchart illustrating the procedure of processing performed when the connection device 2 is connected to the electronic equipment 1 in Embodiment 1. A worker connects appropriate connection device 2 to the electronic equipment 1 to which a function has not yet been set. Here, the USB 3.0 plug 24 is connected to the USB 3.0 socket 18, so that the electronic equipment 1 is connected to the connection device 2 (S11). While the electronic equipment 1 is connected to the connection device 2, the worker performs the operation for activating the electronic equipment 1, and then the electronic equipment 1 is activated (S12). Note that step S11 may be performed while the electronic equipment 1 has already been activated, and the electronic equipment 1 may be restarted at step S12. The setting processing section 31 is activated when the electronic equipment 1 is activated. The setting processing section 31 then detects the potential of each of the connected signal lines 15, 15, . . . and accepts signals indicating the functional level, to detect the functional level determined by the level prescribing section 21 (S13). Note that, in the configuration where the level prescribing section 21 is a non-volatile memory which stores digital data, the setting processing section 31 reads out data indicating the functional level from the level prescribing section 21 at step S13 to detect the determined functional level.

The setting processing section 31 subsequently refers to the information stored in the functional information storage section 32, reads out a designation number associated with the detected functional level from the referred information, and stores the read designation number in the setting storage section 33 (S14). If, for example, the functional information storage section 32 stores the information shown in FIG. 6 and the accepted signals indicating the functional level are in the range between {1, 1, 1, 0, 0} and {0, 1, 1, 1, 0}, the setting processing section 31 reads out the designation number “1” to be stored in the setting storage section 33. The worker then operates the electronic equipment 1 to shut it down, and thus the electronic equipment 1 is shut down (S15). After shut down, the worker pulls out the connection device 2 from the electronic equipment 1, so that the connection device 2 is separated from the electronic equipment 1. This terminates the processing performed when the electronic equipment 1 is connected to the connection device 2.

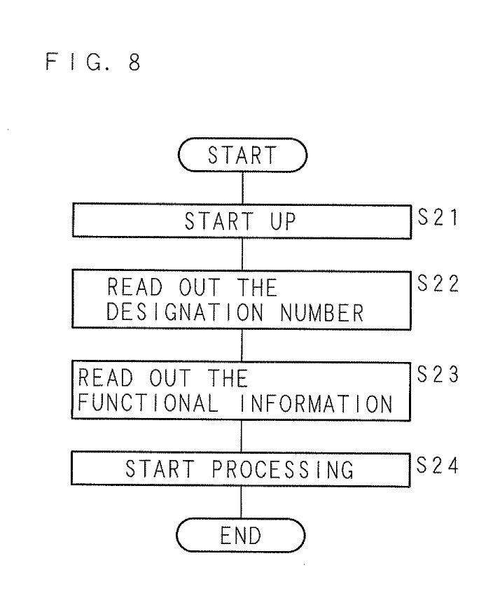

FIG. 8 is a flowchart illustrating the procedure of processing performed when the electronic equipment 1 is activated in Embodiment 1. After executing the processing as shown in FIG. 7, the worker performs operation for activating the electronic equipment 1 from which the connection device 2 has been detached, and thus the electronic equipment 1 is activated, i.e., started up (S21). After start-up, the CPU 16 reads out the designation number stored in the setting storage section 33 (S22). The CPU 16 then refers to the information stored in the functional information storage section 32 to read out the functional information stored therein in association with the read-out designation number (S23). The CPU 16 subsequently makes a RAM 17 store the read-out functional information, and starts the processing in accordance with the functional information stored in the RAM 17 (S24). This terminates the processing performed by the electronic equipment 1 at the time of start-up.

It is noted that the electronic equipment 1 may have a configuration in that the setting storage section 33 stores the functional information in accordance with the functional level, while the CPU 16 executes the processing in accordance with the functional information stored in the setting storage section 33. The electronic equipment 1 may also be configured such that the functional information storage section 32 stores the functional information directly associated with the functional level, while the setting storage section 33 stores the functional information in accordance with the functional level. The contents stored in the setting storage section 33 may not be rewritten, or may be rewritten by resetting. Moreover, the electronic equipment 1 may be configured to have the CPU 16 and the setting processing section 31 that are integrated with each other.

As specifically described above, in the present embodiment, the level of the function executed by the electronic equipment 1 is determined at the connection device 2. The electronic equipment 1 sets details of the function which is actually executed, in accordance with the functional level determined at the connection device 2. In the electronic equipment 1, a function in accordance with any one of the plural types of settings is executed. Thus, plural types of electronic equipment 1 having different functions can be manufactured only by performing appropriate setting, without providing different hardware configurations for the electronic equipment 1. According to the present invention, plural types of electronic equipment can be manufactured at a lower cost compared to the method of realizing plural types of electronic equipment by preparing different hardware configurations. This can also eliminate the need for facilities for preparing different hardware configurations for the electronic equipment 1. In the present embodiment, furthermore, the function is set for the electronic equipment 1 only by connecting the connection device 2 to the electronic equipment 1. A worker does not need to do anything but to connect appropriate connection device 2 to the electronic equipment 1. Thus, any special work that requires expert knowledge is not required at all. This allows a worker without expert knowledge to easily and appropriately perform setting for the electronic equipment 1. Plural types of electronic equipment 1 can, therefore, be manufactured at high efficiency.

Also in the present embodiment, the connection device 2 is connected to the electronic equipment 1 with the interface of USB 3.0, and the electronic equipment 1 detects a functional level via the signal lines 15, 15, . . . which are used for USB 3.0. Since not a special but a general interface is used for setting the function of the electronic equipment 1, necessary manufacturing cost can be reduced. Moreover, an external device using USB 2.0 may be connected to the USB 3.0 socket 18 and the electronic equipment 1 may input or output data to/from the external device. It is thus possible to make effective use of the circuit provided within the electronic equipment 1.

### Embodiment 2

Embodiment 2 illustrates a configuration for setting an executable function by setting whether the operation of plural devices included in the electronic equipment 1 is enabled or disabled. For example, the electronic equipment 1 in which the operation of a specific device is enabled and the electronic equipment 1 in which the operation of the specific device is disabled are manufactured, to provide different types of electronic equipment 1, i.e., high-end electronic equipment 1 and low-end electronic equipment 1.

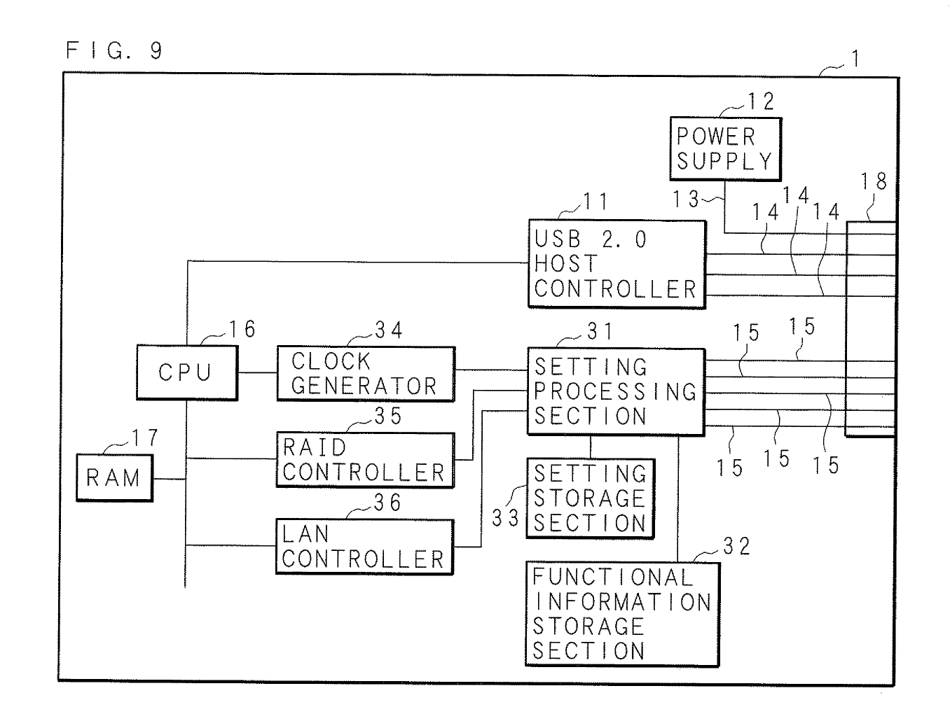

FIG. 9 is a block diagram illustrating the internal functional configuration of the electronic equipment 1 according to Embodiment 2. The functional configuration inside the connection device 2 is similar to that in Embodiment 1. The electronic equipment 1 includes a clock generator 34 for increasing the operating frequency of CPU 16, a RAID (Redundant Arrays of Inexpensive Disks) controller 35 and a LAN (Local Area Network) controller 36. The RAID controller 35 is connected to plural hard disks (not shown), and executes processing for realizing a disk array. The LAN controller 36 is connected to a LAN interface (not shown) and controls transmission of data through LAN. Each device of the clock generator 34, RAID controller 35 and LAN controller 36 corresponds to the function executing section in the present invention. Note that the electronic equipment 1 may also include other devices as the function executing sections.

Each of the clock generator 34, RAID controller 35 and LAN controller 36 is connected to the CPU 16 and the setting processing section 31. The setting processing section 31 performs processing to determine whether the operation of each device is enabled or disabled. Furthermore, the setting processing section 31 is connected to the functional information storage section 32 and the setting storage section 33. The other functional configurations in the electronic equipment 1 are similar to those in Embodiment 1.

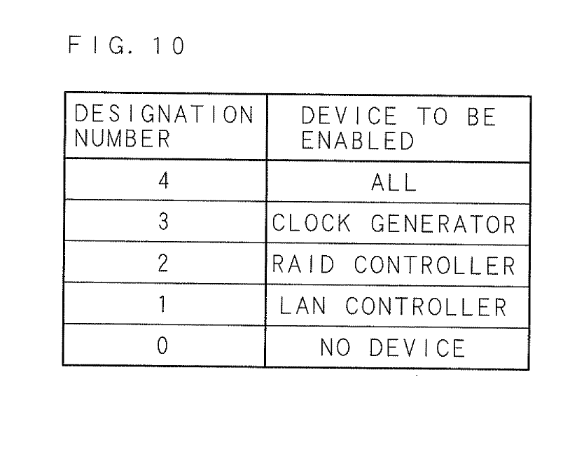

FIG. 10 is a conceptual view illustrating an example of details of the functional information stored in the functional information storage section 32 in Embodiment 2. The functional information storage section 32 stores information designating a device to be enabled among the plural devices of the clock generator 34, RAID controller 35 and LAN controller 36. Moreover, a designation number is attached to each piece of the functional information. In the example of FIG. 10, as the device to be enabled, the designation number “4” is attached to the information designating all the devices of the clock generator 34, RAID controller 35 and LAN controller 36. The designation number “3” is attached to the information designating the clock generator 34, while the designation number “2” is attached to the information designating the RAID controller 35. Moreover, the designation number “1” is attached to the information designating the LAN controller 36, while the designation number “0” is attached to the information indicating that there is no device which enables the operation.

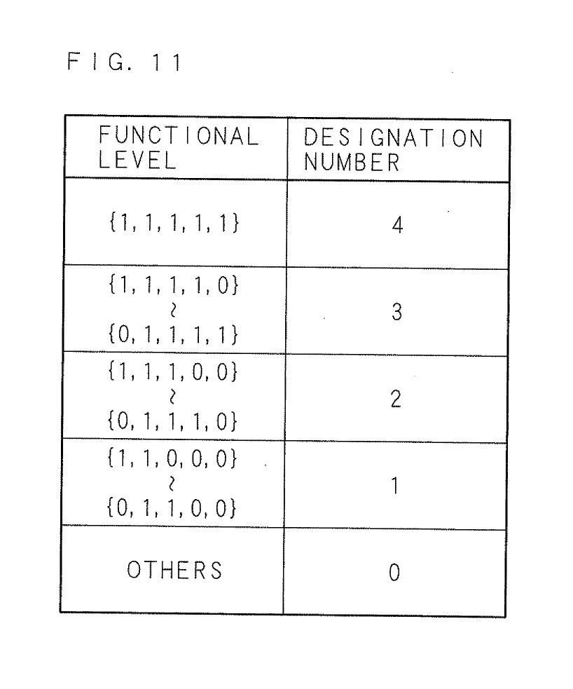

FIG. 11 is a conceptual view illustrating an example of details of information in which a functional level and a designation number are associated with each other in Embodiment 2. The functional information storage section 32 stores the information indicating the range of the functional level corresponding to each designation number. In the example shown in FIG. 11, the signals of {1, 1, 1, 1, 1} indicating the functional level are associated with the designation number “4,” while the signals in the range between {1, 1, 1, 1, 0} and {0, 1, 1, 1, 1} indicating the functional level are associated with the designation number “3.” Moreover, the signals in the range between {1, 1, 1, 0, 0} and {0, 1, 1, 1, 0} indicating the functional level are associated with the designation number “2.” The signals in the range between {1, 1, 0, 0, 0} and {0, 1, 1, 0, 0} indicating the functional level are associated with the designation number “1,” while the signals in the range other than the above indicating the functional level are associated with the designation number “0.” Furthermore, in the state where the level prescribing section 21 is configured with a non-volatile memory, the functional information storage section 32 stores, for example, specific data of the functional levels in association with the respective designation numbers.

The processing for setting the function of the electronic equipment 1 will now be described. In a factory, a dealer or the like, a worker connects the electronic equipment 1 to the connection device 2 to set the function of the electronic equipment 1. For example, at the level prescribing section 21 in the connection device 2, the functional level is determined in accordance with the grade of the electronic equipment 1, i.e. a high-end product, a low-end product or the like. A label indicating the grade of the electronic equipment 1 is shown on the outer surface of the connection device 2.

When connected to the connection device 2, the electronic equipment 1 performs the processing according to the flowchart shown in FIG. 7. A worker connects appropriate connection device 2 to the electronic equipment 1 to which a function has not yet been set. Here, the USB 3.0 plug 24 is connected to the USB 3.0 socket 18, so that the electronic equipment 1 is connected to the connection device 2 (S11). While the electronic equipment 1 is connected to the connection device 2, the worker performs the operation for activating the electronic equipment 1, and then the electronic equipment 1 is activated (S12). The setting processing section 31 is activated when the electronic equipment 1 is activated. The setting processing section 31 subsequently detects the potential of each of the connected signal lines 15, 15, . . . and accepts signals indicating the functional level, to detect the functional level determined by the level prescribing section 21 (S13). The setting processing section 31 subsequently refers to the information stored in the functional information storage section 32, reads out a designation number associated with the detected functional level, and stores the read designation number in the setting storage section 33 (S14). If, for example, the functional information storage section 32 stores the information shown in FIG. 6 and the accepted signals indicating the functional level are in the range between {1, 1, 1, 0, 0} and {0, 1, 1, 1, 0}, the setting processing section 31 reads out the designation number “2” to be stored in the setting storage section 33. The worker then operates the electronic equipment 1 to shut it down, and thus the electronic equipment 1 is shut down (S15). After shut down, the worker pulls out the connection device 2 from the electronic equipment 1, so that the connection device 2 is separated from the electronic equipment 1. This terminates the processing performed when the electronic equipment 1 is connected to the connection device 2.

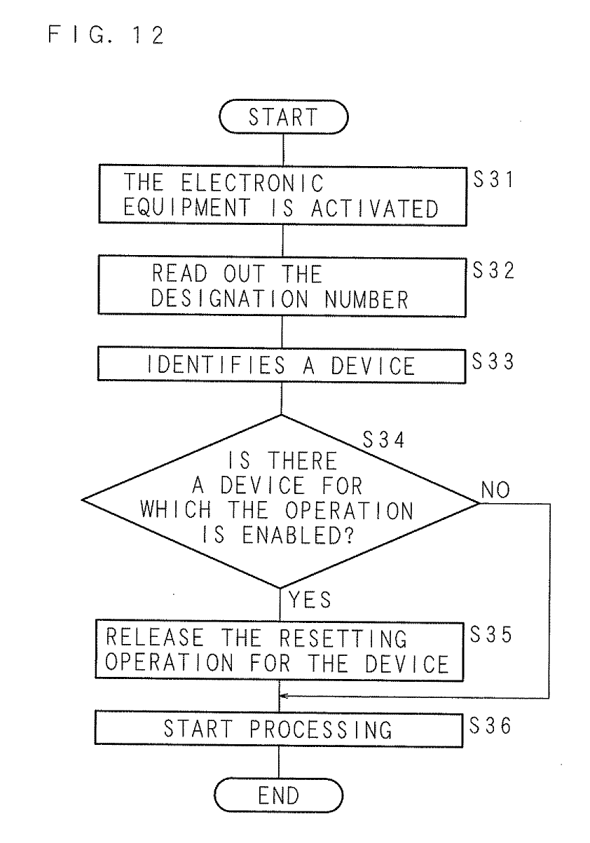

FIG. 12 is a flowchart illustrating the procedure of processing performed when the electronic equipment 1 is activated in Embodiment 2. After executing the processing as shown in FIG. 7, the worker performs operation for activating the electronic equipment 1 from which the connection device 2 has been detached, and thus the electronic equipment 1 is activated (S31). The setting processing section 31 is activated when the electronic equipment 1 is activated, then reads out the designation number stored in the setting storage section 33 (S32). The setting processing section 31 refers to the information stored in the functional information storage section 32, reads out the functional information stored in association with the read-out designation number, and identifies a device for which the operation designated in the functional information is enabled (S33). The setting processing section 31 detects whether or not there is a device for which the operation is enabled (S34). For example, if the designation number read out at step S32 is “0,” the setting processing section 31 detects that there is not device for which the operation is enabled. If the designation number read out at step S32 is a number other than “0,” the setting processing section 31 detects that there is a device for which the operation is enabled.

If there is a device for which the operation is enabled at step S34 (S34: YES), the setting processing section 31 releases the resetting operation for the device identified at step S33 (S35). The reset releasing allows the device to operate, enabling the operation of the device. At step S35, the setting processing section 31 does not release the resetting operation for the device not identified at step S33. Thus, the device stays reset, making it impossible for the device to operate and thus disabling the operation of the device. The CPU 16 then starts the processing using the device for which the resetting operation is released (S36).

If, for example, the signals indicating the functional level are {1, 0, 0, 0, 1}, the operation of the clock generator 34 is enabled. The clock generator 34 performs the processing of increasing the operating frequency of the CPU 16. The CPU 16 then executes information processing in an overclocked state. If the signals indicating the functional level are {1, 0, 0, 1, 0}, the operation of the RAID controller 35 is enabled. The CPU 16 uses the RAID controller 35 to execute the processing using a disk array. If the signals indicating the functional level are {1, 0, 1, 0, 0}, the operation of the LAN controller 36 is enabled. The CPU 16 uses the LAN controller 36 to execute the processing for data transmission through LAN. If the signals indicating the functional level are {1, 1, 1, 1, 1}, the CPU 16 executes the processing using all the devices of the clock generator 34, RAID controller 35 and LAN controller 36.

If, at step S34, there is no device for which its operation is enabled (S34: NO), the setting processing section 31 does not release the resetting operation for any device and proceeds to step S36. The CPU 16 executes the processing not using any device of the clock generator 34, RAID controller 35 and LAN controller 36. With this, the electronic equipment 1 terminates the processing performed at the time of start-up.

As has been specifically described above, in the present embodiment, the electronic equipment 1 enables or disables the operation of each of the plural devices in accordance with the functional level determined at the connection device 2. The electronic equipment 1 executes the processing using a device for which the operation is enabled according to the functional level. If the operation of a different device is enabled, the function executed by the electronic equipment 1 will be different. Accordingly, as a different device is enabled for its operation depending on each of the plural types of functional levels, plural types of electronic equipment having different functions can be realized. In other words, in the present embodiment also, plural types of electronic equipment 1 having different functions can be manufactured only by appropriate setting, without the need for preparing different hardware configurations for the electronic equipment 1. In particular, plural types of electronic equipment 1 of different grades, i.e., from the highest-end product which can use all devices to the lowest-end product which can use no device, can easily be manufactured. Moreover, as in Embodiment 1, the present embodiment can eliminate the need for facilities for preparing different hardware configurations for the electronic equipment 1, allowing a worker with no expert knowledge to easily perform appropriate setting. In the present invention, therefore, plural types of electronic equipment 1 can be manufactured at low cost.

Furthermore, though Embodiments 1 and 2 above showed the case where the electronic equipment 1 is connected to the connection device 2 through USB 3.0 and the processing is performed using a part of the signal lines used for USB 3.0, the present invention may alternatively use an interface other than USB 3.0.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

What is claimed is:

1. An electronic equipment system, comprising:
an electronic equipment; and
a connection device detachable from the electronic equipment, wherein
the connection device includes a level prescribing section at which a level of a function to be executed by the electronic equipment is determined, and wherein
the electronic equipment includes:
a detection section for detecting the level determined at the level prescribing section when the connection device is connected to the electronic equipment; and
a setting section for setting details of the function to be executed by the electronic equipment in accordance with the level detected by the detection section.

2. The electronic equipment system according to claim 1, wherein the setting section includes:
a functional information storage section storing a plurality of types of functional information for determining details of a function executable by the electronic equipment; and
a level association section associating a level of a function to each of the plurality of types of functional information; and
a selection section for selecting any one of the plurality of types of functional information in accordance with the level detected by the detection section, and wherein
the electronic equipment further includes a processing section for performing a process of executing a function determined in the functional information selected by the selection section after the connection device is detached from the electronic equipment.

3. The electronic equipment system according to claim 1, wherein the electronic equipment further includes a plurality of function executing sections each having an individual function, and wherein
the setting section includes:
a level range storage section storing a range of levels which allows operation of each of the plurality of function executing sections; and
an operation setting section which enables operation of a function executing section when the level detected by the detection section is included in a range of levels allowing operation of the function executing section, and disables operation of a function executing section when the level detected by the detection section is not included in the range of levels allowing operation of the function executing section, among the plurality of function executing sections.

4. The electronic equipment system according to claim 1, wherein
the electronic equipment is connected to the connection device by an interface for transmitting data through a plurality of signal lines, and
the detection section is connected to the level prescribing section through a part of the plurality of signal lines when the electronic equipment is connected to the connection device, and detects a level determined at the level prescribing section through the part of the signal lines.

5. An electronic equipment that is detachable from a connection device and that can execute a plurality of types of functions, comprising:
a detection section for detecting a level determined at a connection device, in which a level of a function to be executed is predetermined, when the connection device is connected to the electronic equipment; and
a setting section for setting details of a function to actually be executed among the plurality of types of functions so as to be able to execute a function in accordance with the level detected by the detection section.
